(19) United States
(12) Patent Application Publication
(10) Pub. No.: US 2009/0053866 A1
(43) Pub. Date: Feb. 26, 2009

(54) NONVOLATILE SEMICONDUCTOR MEMORY DEVICE, METHOD FOR DRIVING THE SAME, AND METHOD FOR FABRICATING THE SAME

(75) Inventors: Keiichi Hirooka, Toyama (JP); Katsujirou Arai, Kyoto (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD., Osaka (JP)

(21) Appl. No.: 12/212,892

(22) Filed: Sep. 18, 2008

Related U.S. Application Data
(62) Division of application No. 11/052,811, filed on Feb. 9, 2005, now abandoned.

(30) Foreign Application Priority Data
Feb. 20, 2004 (JP) 2004-45201

(51) Int. Cl. H01L 21/8246; H01L 21/336

(52) U.S. Cl. 438/261; 438/257; 257/E21.409; 257/E21.662

(57) ABSTRACT

A p-type source region 2 and a p-type drain region 3 are formed on the surface of an n-type semiconductor layer 1. In the position located above a channel region interposed between the p-type source region 2 and the p-type drain region 3 and overlapping the p-type drain region 3, a charge accumulation electrode 5 is formed with a tunnel oxide film 4 interposed therebetween. In the position located above the channel region interposed between the p-type source region 2 and the p-type drain region 3 and overlapping the p-type source region 2, a select electrode 7 is formed with an insulating film 6 interposed therebetween. Above the charge accumulation electrode 5, a control electrode 9 is formed with the insulating film 8 interposed therebetween.

### CROSS-REFERENCE TO RELATED APPLICATIONS

This application claims priority under 35 U.S.C. § 119 on Patent Application No. 2004-45201 filed in Japan on Feb. 20, 2004, the entire contents of which are hereby incorporated by reference.

### BACKGROUND OF THE INVENTION

(a) Fields of the Invention

The present invention relates to nonvolatile semiconductor memory devices, methods for driving the device, and methods for fabricating the device. In particular, the present invention relates to nonvolatile semiconductor memory devices formed of flash memories, methods for fabricating such a device, and methods for driving such a device.

(b) Description of Related Art

One of memories well known as electrically erasable programmable nonvolatile memories is a flash memory. The flash memory has the structure in which on a channel region interposed between source and drain regions formed in the surface of a semiconductor substrate, a floating gate electrode (charge accumulation electrode) is formed with a gate insulating film interposed therebetween and above the floating gate electrode, a control gate electrode (control electrode) is formed with a thin interlayer insulating film interposed therebetween. In general, the source region and the drain region are formed of an n-doped layer. Hereinafter, description will be made of an example of a drive system for an n-channel type flash memory called a NOR flash memory.

Writing (programming) in the n-channel type NOR flash memory is performed, for example, as follows. A positive potential is applied to the drain region and the control gate electrode, and thus hot electrons are generated in a portion of the channel region around the drain of the semiconductor substrate. The generated hot electrons are accelerated and injected into the floating gate electrode to perform the writing.

Reading from the n-channel type NOR flash memory is performed, for example, as follows. When a positive potential is applied to the drain region and the control gate electrode, current flows between the source and the drain. The amount of this current differs depending on the amount of charges accumulated in the floating gate electrode, so that the amount of the current is detected to perform the reading.

For erasing of the n-channel type NOR flash memory, the following method is proposed. Utilizing tunneling phenomenon, electrons are emitted from the floating gate electrode to the source region, the drain region or the channel region, thereby performing electrical erasing.

In the n-channel type NOR flash memory, the writing mentioned above is performed on a bit-by-bit basis by selecting a bit line and a word line of a memory cell array, while the erasing mentioned above is performed on all bits in a fixed memory region by one operation. Therefore, the threshold voltage of the memory cell transistor after the erasing of the memory cell array reaches low Vt which is almost 0 V. However, the threshold voltage after the erasing has a wider distribution of Vt than the threshold voltage after the writing, so that in the threshold voltage distribution having become low Vt after the erasing, overerasing may occur in which the threshold voltages of some memory cells (bits) are smaller than 0 V.

If overerased bits are present in the n-channel type flash memory, the bits in turn cause an erroneous reading operation, which is one popular problem for n-channel type flash memories. To avoid this problem, the threshold voltage after the erasing has to be set at a high value having a fixed value or greater. This setting lowers margins for the reading from the memory cell with low Vt after the erasing and from the memory cell with high Vt after the writing. In order to secure those margins, the threshold voltage after the writing has also to be set at a fixed value or greater, which hinders reduction of power consumption and unification of power sources.

To solve the foregoing problems, other than the n-channel type NOR flash memory, various memory cells are proposed which offer reduced power consumption during the writing and erasing. One of the proposed memories is an n-channel type DINOR (divided bit line NOR) flash memory. Hereinafter, description will be made of an example of a drive system for the n-channel type DINOR flash memory.

Writing in the n-channel type DINOR flash memory is electrically performed, for example, by emitting electrons from the floating gate electrode to the drain region using tunneling phenomenon.

Reading from the n-channel type DINOR flash memory is performed, for example, as follows. When a positive potential is applied to the drain region and the control gate electrode, current flows between the source and the drain. The amount of this current depends on the amount of charges accumulated in the floating gate electrode, so that the amount of the current is detected to perform the reading.

Erasing of the n-channel type DINOR flash memory is performed as follows. A positive potential is applied to the control gate electrode, a negative potential is applied to the source region and the semiconductor substrate, and the drain region is set open. By such a condition, electrons are injected from the channel region to the floating gate electrode by FN tunneling phenomenon, thereby performing the erasing.

In the n-channel type DINOR flash memory, the writing mentioned above is performed on a bit-by-bit basis by selecting a bit line and a word line of a memory cell array, while the erasing mentioned above is performed on all bits in a fixed memory region by one operation. That is to say, in the logics of the writing condition and the erasing condition, the drive system of the n-channel type DINOR flash memory is the reverse of that of the n-channel type NOR flash memory. Therefore, in the DINOR flash memory, memory cells are set on a bit-by-bit basis to the state of low Vt by writing, and all bits of a fixed memory region are set to the state of high Vt by one erasing operation. Transition to the state of low Vt by the writing is made bit by bit, which narrows the distribution of low-Vt threshold voltage to suppress the occurrence of overerasing. Consequently, both the threshold voltages after the writing and the erasing can be made lower than those of the NOR flash memory, which is effective in reduction of power consumption and unification of power sources.

The n-channel type flash memory described above, however, has the following problems. For example, in the case of writing in the DINOR type memory, negative and positive potentials are applied to the control gate electrode and the drain region, respectively, to emit to the drain region electrons accumulated in the floating gate electrode. In this writing, a strong electric field is generated between the floating gate electrode and the drain region, and then band-to-band tunneling is induced in a p-well close to the drain region to produce electron-hole pairs. At this time, the holes are accelerated by an electric field of a depletion layer between the drain region and the p-well, and then obtain high energies to become hot holes. Some of the holes having changed to the hot holes are injected into the tunnel oxide film. Generally, the injection of those holes into the tunnel oxide film causes degradation of the tunnel oxide film, which disadvantageously leads to lowered reliability of the flash memory.

To approach the above problem, a p-channel type flash memory is proposed in Japanese Unexamined Patent Publication No. H9-8153. The structure of the p-channel type flash memory has a great difference from the n-channel type flash memory in that the source and drain regions are formed of a p-doped layer. However, the both flash memories are the same in that on the channel region interposed between the source and drain regions formed in the surface of the semiconductor substrate, the floating gate electrode (charge accumulation electrode) is formed with the gate insulating film interposed therebetween and above the floating gate electrode, the control gate electrode (control electrode) is formed with the interlayer insulating film interposed therebetween.

Hereinafter, description will be made of an example of a drive system for the p-channel type flash memory.

An example of writing therein will be first described. First, a positive potential (for example, 10 V) is applied to the control gate electrode and a negative potential (for example, −6 V) is applied to the drain region. The source region is set open and an n-well is set at a ground potential. Thereby, band-to-band tunneling is generated in the drain region to produce electron-hole pairs. Of the pairs, electrons are accelerated in the channel direction by a lateral electric field to become hot electrons with high energies. At this time, since a positive potential is applied to the control gate electrode, the hot electrons can be easily injected into the tunnel oxide film to reach the floating gate electrode. The writing is thus performed.

Through this writing, each memory cell can be set to the state of low Vt (the state of negative sign and small absolute value since the transistor used is a p-channel type transistor). In this writing, of the electron-hole pairs produced by the band-to-band tunneling, the holes are pulled to the drain region and scatter in the drain region having a high hole density. By the scattering, the energies of the holes are taken away, so that the holes are never changed to hot holes. Consequently, degradation of the reliability of the tunnel oxide film is eliminated.

Reading from the p-channel type flash memory is performed, for example, as follows. A negative potential (for example, −3.3 V) is applied to the control gate electrode, a negative potential (for example, −1 V) is applied to the drain region, and a ground potential is applied to the source region and the n-well. By such a condition, current flows between the source and the drain. The amount of this current depends on the amount of charges having already been accumulated in the floating gate electrode, so that the amount of the current is detected to perform the reading.

Erasing of the p-channel type flash memory is performed, for example, as follows. A negative potential (for example, −10 V) is applied to the control gate electrode, a positive potential (for example, 10 V) is applied to the source region and the n-well, and the drain region is set open. By such a condition, tunneling phenomenon is used to emit electrons from the floating gate electrode to the channel region, thereby electrically performing the erasing. The erasing operation can form a memory cell in the state of high Vt (the state of negative sign and large absolute value since the transistor used is a p-channel type transistor).

However, as described in U.S. Pat. No. 5,912,842, the p-channel type flash memory as shown above has a problem that if an unselected bit is erroneously written (disturbed) in the writing, the memory has only a small margin for the disturbance. This problem will be described in detail.

In an unselected bit in the above-mentioned p-channel type flash memory located on a common bit line with a bit selected in the writing, a ground potential is applied to the control gate electrode, −6 V is applied to the drain region, the source region is set open, and a ground potential is applied to the n-well. In such a condition, band-to-band tunneling is generated in the drain region of the unselected bit to produce electron-hole pairs, and the potential of the floating gate electrode of this bit becomes about −1 V by capacitive coupling with the drain region and the control gate electrode. Then, by an electric field generated between the floating gate electrode and the drain region, the electrons of the electron-hole pairs produced in the drain region by band-to-band tunneling are injected also into the floating gate electrode of the unselected bit, that is to say, disturbance occurs. In the p-channel type flash memory, the memory cell after the writing has a Vt of about −2.5 V, and the memory cell after the erasing has a Vt of about −4.2 V. The difference between both is small, which causes the problem that influences of the disturbance mentioned above cannot be neglected.

To solve the above problems, a p-channel type flash memory with two-transistor (2T) structure whose memory cells are each formed of two transistors is proposed in U.S. Pat. No. 5,912,842. The p-channel type flash memory with 2T structure will be described with reference to FIG. 12.

FIG. 12 shows a cross section of the p-channel type flash memory of 2T structure. The p-channel type flash memory of 2T structure is configured so that two transistors, that is, a memory cell transistor 201 having a floating gate electrode 105 and a select transistor 202 are adjacent to each other. These transistors form one bit.

The memory cell transistor 201 is formed on a first channel region interposed between a p-type source region 102 and a first drain region 111 both formed in the surface of a semiconductor substrate 101. Above the first channel region, a floating gate electrode (charge accumulation electrode) 105 is formed with a gate insulating film 104 interposed therebetween. Above the floating gate electrode 105, a control gate electrode (control electrode) 109 is formed with an interlayer insulating film 108 interposed therebetween. The select transistor 202 is formed on a second channel region interposed between the first drain region 111 of p-type and a second drain region 112 both formed in the surface of the semiconductor substrate 101. Above the second channel region, a select gate electrode 107 is formed with an insulating film 106 interposed therebetween.

Hereinafter, description will be made of an example of a drive system for the p-channel type flash memory of 2T structure. First, an example of writing operation will be described. A positive potential (for example, 8 V) is applied to the control gate electrode 109, a negative potential (for example, −5 V) is applied to the second drain region 112, the source region 102 is set open, Vcc (for example, 3 V) is applied to the n-well (substrate 101), and a negative potential (for example, −7.5 V) is applied to the select gate electrode 107. Thereby, the select transistor 202 is in the ON state and the first drain region 111 has the same potential as the second drain region 112. Then, band-to-band tunneling is generated in the first drain region 111 to produce electron-hole pairs.

Of these pairs, electrons are accelerated in the channel direction by a lateral electric field to become hot electrons with high energies. At this time, since a positive potential is applied to the control gate electrode 109, the hot electrons can be easily injected into the tunnel oxide film 104 to reach the floating gate electrode 105. The writing is thus performed. In this writing, of the electron-hole pairs produced by the band-to-band tunneling, the holes are pulled to the first drain region 111 and scatter in the first drain region 111 having a high hole density. By the scattering, the energies of the holes are taken away, so that the holes are never changed to hot holes. Consequently, the above-mentioned problem of degradation in reliability of the flash memory due to hot holes can be avoided.

Reading from the p-channel type flash memory of 2T structure is performed, for example, as follows. Vcc (for example, 3 V) is applied to the control gate electrode 109, a positive potential (for example, 1.2 V) is applied to the second drain region 112, Vcc (for example, 3 V) is applied to the source region 102 and the n-well (the substrate 101), and a ground potential is applied to the select gate electrode 107. By such a condition, current flows between the source and the drain. The amount of this current depends on the amount of charges accumulated in the floating gate electrode 105, so that the amount of the current is detected to perform the reading.

Erasing of the p-channel type flash memory of 2T structure is performed, for example, as follows. A negative potential (for example, −8.5 V) is applied to the control gate electrode 109, a positive potential (for example, 8.5 V) is applied to the source region 102 and the n-well, and the second drain region 112 and the select gate electrode 107 are set open. By such a condition, tunneling phenomenon is used to emit electrons from the floating gate electrode 105 to the channel region, thereby electrically performing the erasing.

FIG. 13 roughly shows the threshold voltage distributions of the memory cell transistors in the p-channel type flash memory of 1T (transistor) structure (dotted curve) and the p-channel type flash memory of 2T structure (solid curve), which are obtained after the writing and the erasing. Referring to FIG. 13, for the memory of 1T structure, it is necessary to set the threshold voltage at a negative voltage both after the writing and after the erasing. Therefore, a margin for the set value of Vt even in consideration of the Vt distributions after the writing and after the erasing is narrow. On the other hands, for the memory of 2T structure, the presence of the select transistor eliminates the limitation in which the threshold voltage thereof is always set at a negative value. From this, it is found that the memory of 2T structure provides an advantage of a widened margin for the set value of Vt in consideration of the Vt distributions after the writing and after the erasing.

### SUMMARY OF THE INVENTION

In the p-channel type flash memory of 2T structure shown above, however, one memory cell has two transistors. This causes a problem that it is difficult to decrease the area occupied by the memory cell. Considering that particularly in erasing operation, the erasing efficiency is better as the area of the floating gate electrode facing the semiconductor substrate with the tunnel oxide film interposed therebetween increases, it is more desirable to allow a greater area of the floating gate electrode facing the semiconductor substrate with the tunnel oxide film interposed therebetween. That is to say, it is necessary to secure large gate length and width of the memory cell. However, particularly for the memory cell of 2T structure, this goes against the trend toward the reduction of the occupied area.

The present invention has been made in view of the foregoing, and its object is to provide a nonvolatile semiconductor memory device capable of securing the advantages of the p-channel type flash memory of 2T structure and concurrently attaining reduction of the areas of memory cells and high density packing of the memory cells, and to provide a method for fabricating such a device and a method for driving a nonvolatile semiconductor memory device.

A first nonvolatile semiconductor memory device of the present invention comprises: an n-type semiconductor layer; a p-type source region and a p-type drain region formed apart from each other to extend inwardly from the surface of the n-type semiconductor layer; a first insulating film as a tunnel insulating film formed on the n-type semiconductor layer; a charge accumulation electrode formed across part of an upper portion of a channel region and part of an upper portion of the p-type drain region so that the first insulating film is interposed between the charge accumulation electrode and the n-type semiconductor layer, the channel region being part of the n-type semiconductor layer located between the p-type source region and the p-type drain region; a control electrode formed above the charge accumulation electrode with a second insulating film interposed therebetween; and a select electrode formed across another part of the upper portion of the channel region and part of an upper portion of the p-type source region so that a third insulating film formed on the n-type semiconductor layer is interposed between the selected electrode and the n-type semiconductor layer. The select electrode adjoins one side wall of the charge accumulation electrode with a fourth insulating film interposed therebetween.

A second nonvolatile semiconductor memory device of the present invention comprises: an n-type semiconductor layer; a p-type drain region formed to extend inwardly from the surface of the n-type semiconductor layer; two p-type source regions formed to extend inwardly from the surface of the n-type semiconductor layer and located apart from both sides of the p-type drain region, respectively; a first insulating film as a tunnel insulating film formed on the n-type semiconductor layer; two charge accumulation electrodes each formed across part of an upper portion of corresponding one of two channel regions and part of an upper portion of the p-type drain region so that the first insulating film is interposed between the corresponding charge accumulation electrode and the n-type semiconductor layer, the two channel regions each being part of the n-type semiconductor layer located between the p-type drain region and corresponding one of the two p-type source regions; two control electrodes each formed above the corresponding charge accumulation electrode with a second insulating film interposed therebetween; and two select electrodes each formed across another part of the upper portion of the corresponding one of the channel regions and part of an upper portion of corresponding one of the p-type source regions so that a third insulating film formed on the n-type semiconductor layer is interposed between each said select electrode and the n-type semiconductor layer. Each of the select electrodes adjoins one side wall of the corresponding charge accumulation electrode with a fourth insulating film interposed therebetween. Two gate electrode structures each comprising the first insulating film, one said charge accumulation electrode, the second insulating film, one said select electrode, the third insulating film, one said control electrode, and the fourth insulating film are symmetrical with respect to the drain region.

A third nonvolatile semiconductor memory device of the present invention comprises: an n-type semiconductor layer; a p-type source region and a p-type drain region formed apart from each other to extend inwardly from the surface of the n-type semiconductor layer; a first insulating film as a tunnel insulating film formed on the n-type semiconductor layer; a charge accumulation electrode formed across part of an upper portion of a channel region and part of an upper portion of the p-type source region so that the first insulating film is interposed between the charge accumulation electrode and the n-type semiconductor layer, the channel region being part of the n-type semiconductor layer located between the p-type source region and the p-type drain region; a control electrode formed above the charge accumulation electrode with a second insulating film interposed therebetween; and a select electrode formed across another part of the upper portion of the channel region and part of an upper portion of the p-type drain region so that a third insulating film formed on the n-type semiconductor layer is interposed between the select electrode and the n-type semiconductor layer. The select electrode adjoins one side wall of the charge accumulation electrode with a fourth insulating film interposed therebetween.

A fourth nonvolatile semiconductor memory device of the present invention comprises: an n-type semiconductor layer; a p-type source region formed to extend inwardly from the surface of the n-type semiconductor layer; two p-type drain regions formed to extend inwardly from the surface of the n-type semiconductor layer and located apart from both sides of the p-type source region, respectively; a first insulating film as a tunnel insulating film formed on the n-type semiconductor layer; two charge accumulation electrodes each formed across part of an upper portion of corresponding one of two channel regions and part of an upper portion of the p-type source region so that the first insulating film is interposed between the corresponding charge accumulation electrode and the n-type semiconductor layer, the two channel regions each being part of the n-type semiconductor layer located between the p-type source region and corresponding one of the two p-type drain regions; two control electrodes each formed above the corresponding charge accumulation electrode with a second insulating film interposed therebetween; and two select electrodes each formed across another part of the upper portion of corresponding one of the channel regions and part of an upper portion of corresponding one of the p-type drain regions so that a third insulating film formed on the n-type semiconductor layer is interposed between each said select electrode and the n-type semiconductor layer. Each of the select electrodes adjoins one side wall of the corresponding charge accumulation electrode with a fourth insulating film interposed therebetween. Two gate electrode structures each comprising the first insulating film, one said charge accumulation electrode, the second insulating film, one said select electrode, the third insulating film, one said control electrode, and the fourth insulating film are symmetrical with respect to the source region.

In one embodiment, the p-type source region, the p-type drain region, the charge accumulation electrode, the control electrode, and the select electrode constitute a memory cell, a plurality of said memory cells are arranged on the surface of the n-type semiconductor layer in rows and columns intersecting each other, thereby constituting a memory cell array, the control electrodes for the memory cell array extend continuously in the column direction for every certain number of the memory cells to form word lines for respective columns, the select electrodes for the memory cell array extend continuously in the column direction for said every certain number of the memory cells to form select gate lines for respective columns, a plurality of source lines extending in the column direction and substantially parallel to each other are provided and each said source line is formed so that a set of the p-type source regions aligned in the column direction are connected to each other, and a plurality of bit lines extending in the row direction and substantially parallel to each other are provided and each said bit line is formed so that a set of the p-type drain regions aligned in the row direction are connected to each other.

In one embodiment, one of the p-type source regions, the p-type drain region, one of the charge accumulation electrodes, one of the control electrodes, and one of the select electrodes constitute a memory cell, a plurality of said memory cells are arranged on the surface of the n-type semiconductor layer in rows and columns intersecting each other, thereby constituting a memory cell array, the control electrodes for the memory cell array extend continuously in the column direction for every certain number of the memory cells to form word lines for respective columns, the select electrodes for the memory cell array extend continuously in the column direction for said every certain number of the memory cells to form select gate lines for respective columns, a plurality of source lines extending in the column direction and substantially parallel to each other are provided and each said source line is formed so that a set of the p-type source regions aligned in the column direction are connected to each other, and a plurality of bit lines extending in the row direction and substantially parallel to each other are provided and each said bit line is formed so that a set of the p-type drain regions aligned in the row direction are connected to each other.

In one embodiment, the p-type source region, the p-type drain region, the charge accumulation electrode, the control electrode, and the select electrode constitute a memory cell, a plurality of said memory cells are arranged on the surface of the n-type semiconductor layer in rows and columns intersecting each other, thereby constituting a memory cell array, the control electrodes for the memory cell array extend continuously in the column direction for every certain number of the memory cells to form word lines for respective columns, the select electrodes for the memory cell array extend continuously in the column direction for said every certain number of the memory cells to form select gate lines for respective columns, a plurality of source lines extending in the column direction and substantially parallel to each other are provided and each said source line is formed so that a set of the p-type source regions aligned in the column direction are connected to each other, and a plurality of bit lines extending in the row direction and substantially parallel to each other are provided and each said bit line is formed so that a set of the p-type drain regions aligned in the row direction are connected to each other.

In one embodiment, the p-type source region, one of the p-type drain regions, one of the charge accumulation electrodes, one of the control electrodes, and one of the select electrodes constitute a memory cell, a plurality of said memory cells are arranged on the surface of the n-type semiconductor layer in rows and columns intersecting each other, thereby constituting a memory cell array, the control electrodes for the memory cell array extend continuously in the column direction for every certain number of the memory cells to form word lines for respective columns, the select electrodes for the memory cell array extend continuously in the column direction for said every certain number of the memory cells to form select gate lines for respective columns, a plurality of source lines extending in the column direction and substantially parallel to each other are provided and each said source line is formed so that a set of the p-type source regions aligned in the column direction are connected to each other, and a plurality of bit lines extending in the row direction and substantially parallel to each other are provided and each said bit line is formed so that a set of the p-type drain regions aligned in the row direction are connected to each other.

A first method for driving a nonvolatile semiconductor memory device according to the present invention performs writing of information in such a manner that in the first or second nonvolatile semiconductor memory device of the present invention, a positive potential relative to the n-type semiconductor layer is applied to the control electrode and a negative potential relative to the n-type semiconductor layer is applied to the p-type drain region, whereby electrons are injected through the first insulating film into the charge accumulation electrode.

A second method for driving a nonvolatile semiconductor memory device according to the present invention performs writing of information in such a manner that in the first or second nonvolatile semiconductor memory device of the present invention, hot electrons are induced by band-to-band tunneling at a pn junction between the p-type drain region and the n-type semiconductor layer, and the induced hot electrons are injected into the charge accumulation electrode.

A third method for driving a nonvolatile semiconductor memory device according to the present invention performs writing of information in such a manner that in the first or second nonvolatile semiconductor memory device of the present invention, hot electrons are generated by avalanche breakdown at a pn junction between the p-type drain region and the n-type semiconductor layer, and the generated hot electrons are injected into the charge accumulation electrode.

A fourth method for driving a nonvolatile semiconductor memory device according to the present invention performs erasing of information in such a manner that in the first or second nonvolatile semiconductor memory device of the present invention, a negative potential is applied to the control electrode and a positive potential is applied to the p-type source region, whereby electrons are emitted from the charge accumulation electrode through the first insulating film to the channel region.

A fifth method for driving a nonvolatile semiconductor memory device according to the present invention performs erasing of information in such a manner that in the first or second nonvolatile semiconductor memory device of the present invention, electrons are emitted by FN tunneling phenomenon from the charge accumulation electrode through the first insulating film to the channel region.

A sixth method for driving a nonvolatile semiconductor memory device according to the present invention performs writing of information in such a manner that in the third or fourth nonvolatile semiconductor memory device of the present invention, a negative potential relative to the n-type semiconductor layer is applied to the control electrode and a positive potential relative to the n-type semiconductor layer is applied to the p-type drain region, whereby electrons are emitted from the charge accumulation electrode through the first insulating film to the p-type drain region.

A seventh method for driving a nonvolatile semiconductor memory device according to the present invention performs writing of information in such a manner that in the third or fourth nonvolatile semiconductor memory device of the present invention, electrons are emitted by FN tunneling phenomenon from the charge accumulation electrode through the first insulating film to the p-type drain region.

An eighth method for driving a nonvolatile semiconductor memory device according to the present invention performs erasing of information in such a manner that in the third or fourth nonvolatile semiconductor memory device of the present invention, a positive potential relative to the n-type semiconductor layer is applied to the control electrode and a negative potential is applied to the p-type source region, whereby electrons are injected through the first insulating film into the charge accumulation electrode.

A ninth method for driving a nonvolatile semiconductor memory device according to the present invention performs erasing of information in such a manner that in the third or fourth nonvolatile semiconductor memory device of the present invention, hot electrons are induced by band-to-band tunneling at a pn junction between the p-type source region and the n-type semiconductor layer, and the induced hot electrons are injected into the charge accumulation electrode.

A tenth method for driving a nonvolatile semiconductor memory device according to the present invention performs erasing of information in such a manner that in the third or fourth nonvolatile semiconductor memory device of the present invention, hot electrons are generated by avalanche breakdown at a pn junction between the p-type source region and the n-type semiconductor layer, and the generated hot electrons are injected into the charge accumulation electrode.

A method for fabricating a nonvolatile semiconductor memory device according to the present invention comprises the steps of: forming a first insulating film on a semiconductor layer of a first conductivity type; depositing a first conductor film on the first insulating film; selectively removing part of the first conductor film; forming a second insulating film on the first conductor film; depositing a second conductor film on the second insulating film; removing parts of an electrode structure layer composed of the first conductor film, the second insulating film, and the second conductor film selectively and perpendicularly to the surface of the semiconductor layer of the first conductivity type, thereby forming the unremoved parts in multiple strips extending in the substantially orthogonal direction to the direction in which the removal of the first conductor film has been conducted; forming a third insulating film on portions of the surface of the semiconductor layer of the first conductivity type from which the electrode structure layer has been removed, forming fourth insulating films on both side walls of each said strip of the electrode structure layer, and then forming third conductor films on the fourth insulating films, respectively, to provide the third conductor films as select electrodes; removing a center portion of each said strip of the electrode structure layer along the direction in which the strip extends, thereby dividing the single strip in two; and forming a doped region of a second conductivity type in the semiconductor layer of the first conductivity type by using the electrode structure layer as a mask, the second conductivity type being different from the first conductivity type.

In one embodiment, the first conductivity type is an n-type, and the second conductivity type is a p-type.

### BRIEF DESCRIPTION OF THE DRAWINGS

FIG. 1A is a plan view of a nonvolatile semiconductor memory device according to a first embodiment of the present invention, and FIG. 1B is a sectional view taken along the line A-A′ in FIG. 1A.

FIG. 2 is a diagram showing the distribution of the Vt value of the nonvolatile semiconductor memory device according to the first embodiment of the present invention, which is obtained after writing and after erasing.

FIG. 3A is a plan view of a nonvolatile semiconductor memory device according to a second embodiment of the present invention, and FIG. 3B is a sectional view taken along the line A-A′ in FIG. 3A.

FIG. 4 is a diagram showing the distributions of the Vt values of the nonvolatile semiconductor memory device according to the second embodiment of the present invention, which are obtained after writing and after erasing.

FIG. 5A is a sectional view of a fabrication step of the nonvolatile semiconductor memory device according to the present invention, which is taken along the line A-A′, and FIG. 5B is a sectional view thereof taken along the line B-B′.

FIG. 6A is a sectional view of a fabrication step of the nonvolatile semiconductor memory device according to the present invention, which is taken along the line A-A′, and FIG. 6B is a sectional view thereof taken along the line B-B′.

FIG. 7A is a sectional view of a fabrication step of the nonvolatile semiconductor memory device according to the present invention, which is taken along the line A-A′, and FIG. 7B is a sectional view thereof taken along the line B-B′.

FIG. 8A is a sectional view of a fabrication step of the nonvolatile semiconductor memory device according to the present invention, which is taken along the line A-A′, and FIG. 8B is a sectional view thereof taken along the line B-B′.

FIG. 9A is a sectional view of a fabrication step of the nonvolatile semiconductor memory device according to the present invention, which is taken along the line A-A′, and FIG. 9B is a sectional view thereof taken along the line B-B′.

FIG. 10A is a sectional view of a fabrication step of the nonvolatile semiconductor memory device according to the present invention, which is taken along the line A-A′, and FIG. 10B is a sectional view thereof taken along the line B-B′.

FIG. 11A is a sectional view of a fabrication step of the nonvolatile semiconductor memory device according to the present invention, which is taken along the line A-A′, and FIG. 11B is a sectional view thereof taken along the line B-B′.

FIG. 12 is a sectional view of a conventional nonvolatile semiconductor memory device.

FIG. 13 is a diagram showing the Vt distributions of the conventional nonvolatile semiconductor memory device obtained after writing and after erasing.

FIG. 14 is a circuit diagram of the first embodiment.

FIG. 15 is a circuit diagram of the second embodiment.

### DETAILED DESCRIPTION OF THE PREFERRED EMBODIMENTS

Hereinafter, embodiments of the present invention will be described in detail based on the accompanying drawings.

### First Embodiment

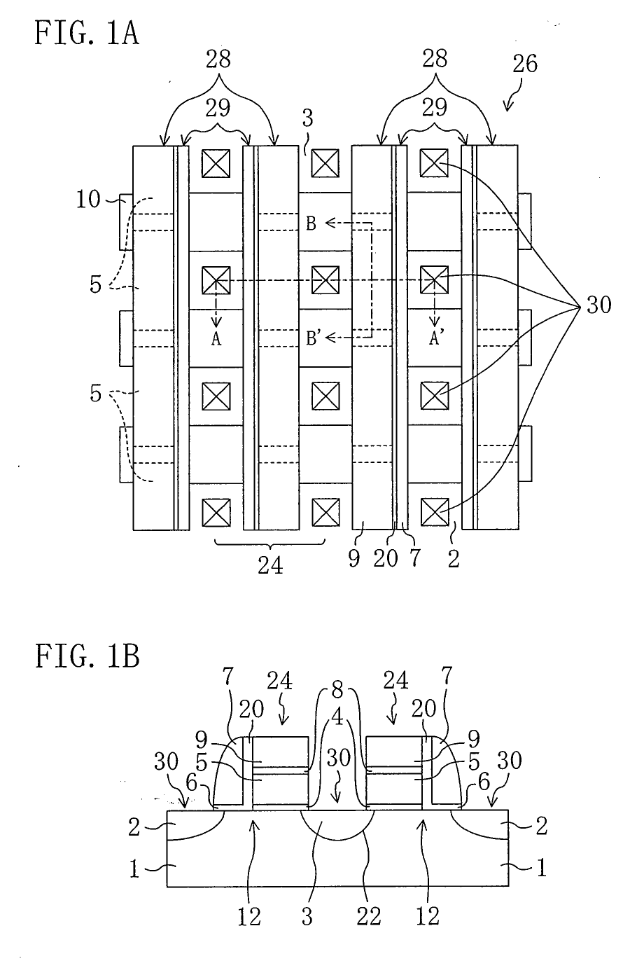

FIG. 1 is schematic views showing the structure of a nonvolatile semiconductor memory device according to a first embodiment of the present invention. FIG. 1A is a plan view of a memory cell array 26, and FIG. 1B is a sectional view of a portion of a memory cell 24 taken along the line A-A′ in FIG. 1A. The nonvolatile semiconductor memory device of the first embodiment is composed of a p-channel type memory cell of 2T structure in which one memory cell 24 has two-transistor structure, and as shown in the sectional view, the cross section A-A′ includes two memory cells 24 and 24. In the memory cell array 26 in this embodiment, a plurality of memory cells 24, 24, . . . are arranged in the vertical and horizontal directions in FIG. 1A. The vertical direction in this figure is called the column direction and the horizontal direction therein orthogonal to the column direction is called the row direction. Note that in FIGS. 1A and 1B, illustration of source and bit lines is omitted, but in fact they are on the memory cells 24, 24, . . . .

As shown in FIGS. 1A and 1B, in the nonvolatile semiconductor memory device of the first embodiment, a p-type drain region 3 is formed to extend inwardly from the surface of an n-type semiconductor layer 1, and on both sides of the drain region 3, two p-type source regions 2 and 2 are spaced from the p-type drain region 3, respectively. In this structure, the n-type semiconductor layer 1 may be an n-type semiconductor substrate or an n-well formed on a semiconductor substrate. Two channel regions 12 and 12 (portions of the n-type semiconductor layer 1) are interposed between the p-type drain region 3 and the two p-type source regions 2, respectively. Across (in the position overlapping) parts of the upper portions of the two channel regions 12 and 12 and part of the upper portion of the p-type drain region 3, two floating gate electrodes (charge accumulation electrodes) 5 and 5 are formed to interpose thin tunnel insulating films (first insulating films) 4 and 4 as gate oxide films therebetween, respectively. Above the floating gate electrodes 5 and 5, two control gate electrodes (control electrodes) 9 and 9 are formed with second insulating films 8 and 8 interposed therebetween, respectively.

Across (in the position overlapping) other parts of the upper portions of the channel regions 12 and 12 and parts of the upper portions of the p-type, source regions 2 and 2, two select gate electrodes (select electrodes) 7 and 7 are formed with third insulating films 6 and 6 interposed therebetween, respectively. The select gate electrodes 7 and 7 are adjacent to side walls of the floating gate electrodes 5 and 5 and the control gate electrodes 9 and 9, respectively, so that fourth insulating films 20 and 20 are interposed between the respective side walls which are located on the channel regions 12 and 12 and select gate electrodes 7 and 7. The p-type source region 2, p-type drain region 3, floating gate electrode 5, control gate electrode 9 and select gate electrode 7 constitute a single memory cell 24. The shapes of the two adjacent memory cells 24 and 24 shown in FIG. 1B are symmetrical with respect to the p-type drain region 3. Specifically, in the two adjacent memory cells 24 and 24, side walls exposing the floating gate electrodes 5 and 5 and the control gate electrodes 9 and 9 face each other, and the select gate electrodes 7 and 7 are formed on the respective side walls opposite to the facing side walls. The adjacent memory cells 24 and 24 share the p-type drain region 3 and are arranged symmetrically with respect to the p-type drain region 3. That is to say, two gate electrode structures (the structures of the memory cells 24 other than the p-type source regions 2 and the p-type drain region 3) composed of the first insulating films 4 and 4, the charge accumulation electrodes 5 and 5, the second insulating films 8 and 8, the select electrodes 7 and 7, the third insulating films 6 and 6, the control electrodes 7 and 7, and the fourth insulating films 20 and 20 are of symmetrical configuration.

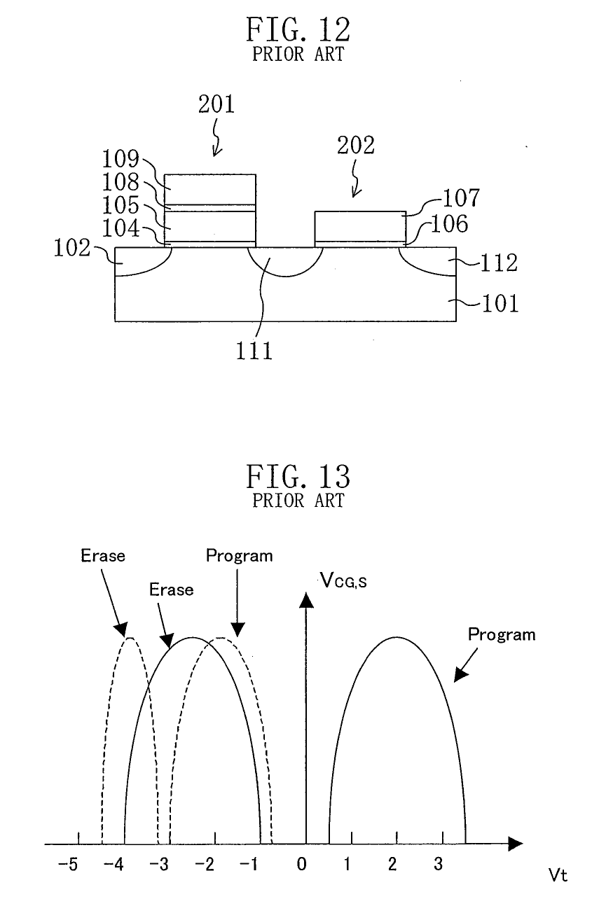

By such a structure of each memory cell 24, it is found that the memory cell transistor and the select transistor are integrally formed with the fourth insulating film 6 interposed therebetween. Therefore, by forming the select electrode 7 in a self-aligned manner and eliminating the first drain region (111 in FIG. 12) in the conventional p-channel type flash memory cell of 2T structure, the flash memory cell of the first embodiment can attain reduction of the area occupied by the memory cell and high density of the memory cell unlike the conventional p-channel type flash memory cell of 2T structure. That is to say, since in the conventional p-channel type flash memory cell of 2T structure shown in FIG. 12, the memory cell transistor 201 and the select transistor 202 are formed separately from each other, the two drain regions 111 and 112 and the two channel regions are required therein. In contrast to this, in the memory cell 24 of the first embodiment, an integral formation of the memory cell transistor and the select transistor reduces the numbers of drain regions 3 and channel regions 12 to one each, whereby the area occupied by each memory cell 24 is reduced to about half.

In the first embodiment, it is also considered that the memory cell transistor and the select transistor share the one channel region 12 and treat it as divided areas. Note that contacts 30 are formed on the p-type drain region 3 and the p-type source regions 2, respectively. The contact on the p-type drain region 3 is connected to the bit line and the contact on the p-type source region 2 is connected to the source line. The control gate electrodes 9 extend continuously in the column direction to form word lines 28. The select gate electrodes 7 also extend continuously in the column direction to form select gate lines 29.

In the nonvolatile semiconductor memory device with the structure described above according to the first embodiment, a method for performing writing (programming) therein will be described below.

A positive potential necessary for writing (for example, 8 V) is applied to the control electrode 9, a negative potential necessary for writing (for example, −5 V) is applied to the drain region 3, the select electrode 7 and the source region 2 are set open, and the n-type semiconductor layer 1 is set at Vcc (for example, 3 V). Thereby, band-to-band tunneling is generated at a pn junction 22 of the drain region 3 to produce electron-hole pairs. Of the pairs, the electrons are accelerated in the channel direction by a horizontal electric field to become electrons with high energies (hot electrons). That is to say, induction by band-to-band tunneling generates hot electrons at the pn junction 22. At this time, since a positive potential is applied to the control electrode 9, these hot electrons can be easily injected into the first insulating film 4 to reach the charge accumulation electrode 5, thereby performing writing. That is, in the first embodiment, the state in which electrons are accumulated in the charge accumulation electrode 5 is defined as the state of being written. In this writing, a positive potential relative to the n-type semiconductor layer 1 is applied to the control electrode 9, and a negative potential relative to the n-type semiconductor layer 1 is applied to the p-type drain region 3.

Of the electron-hole pairs produced by the band-to-band tunneling in this writing, the holes are pulled to the drain region 3 and scatter in the drain region 3 having a high hole density. By the scattering, the energies of the holes are taken away, so that the holes are never changed to hot holes. Therefore, similarly to the device described in Japanese Unexamined Patent Publication No. H9-8153, which has been mentioned in Description of Related Art, reduction of reliability of the nonvolatile semiconductor memory device can be prevented which is caused by injecting the holes having changed to hot holes into the tunnel insulating film 4 below the charge accumulation electrode 5. In this writing, for unselected bits sharing the drain region 3 with the adjacent bit selected for the writing, disturbance may arise like the technique described in Japanese Unexamined Patent Publication No. 9-8153. However, since, similarly to the technique described in U.S. Pat. No. 5,912,842, the select transistor is present in the first embodiment, margins for the Vt distributions after the writing and after the erasing can be widened. As a result, the advantage offered by 2T structure is maintained. Moreover, adjustment of the writing time, bias, or the like controls the amount of fluctuation in the Vt distribution to a desired value or smaller, thereby avoiding the problem of disturbance fluctuation.

A negative voltage higher in absolute value than that used in the writing by the band-to-band tunneling may be applied to the drain region 3 to perform writing. In this case, avalanche breakdown occurs at the pn junction 22 between the drain region 3 and the n-type semiconductor layer 1, and the current occurring by the avalanche breakdown generates hot electrons. By a positive potential applied to the control electrode 9, these hot electrons are injected into the charge accumulation electrode 5, thereby performing writing.

In the nonvolatile semiconductor memory device of the first embodiment, writing is performed on a single bit of each memory cell 24 by selecting a bit line connected to the contact 30 with the drain region 3 and a word line 28 also used as the control electrode 9.

Next description will now be made of an erasing method of the nonvolatile semiconductor memory device of the first embodiment.

A negative potential necessary for erasing (for example, −8.5 V) is applied to the control electrode 9, a positive potential necessary for erasing (for example, 8.5 V) is applied to the p-type source region 2, the n-type semiconductor layer 1 and the select electrode 7, and the p-type drain region 3 is set open. Thereby, electrons are emitted from the charge accumulation electrode 5 through the first insulating film 4 to the channel region 12 to electrically perform erasing. That is to say, in the first embodiment, the state in which electrons are pulled out from the charge accumulation electrode 5 is defined as the state of being erased. Such an electron emitting arises by utilizing FN tunneling phenomenon (Fowler-Nordheim tunneling). In addition, by selecting a source line connected to the contact 30 with the source region 2, this erasing can be performed by one operation on all the memory cells 24, 24, belonging to the selected source line.

Next description will now be made of a reading method of the nonvolatile semiconductor memory device of the first embodiment.

Vcc (for example, 3 V) is applied to the p-type source region 2, and a positive potential (for example, 1.2 V) is applied to the p-type drain region 3. Vcc (for example, 3 V) is applied to the control electrode 9 and the n-type semiconductor layer 1, and a ground potential is applied to the select electrode 7. By such a condition, current flows between the source and the drain. The amount of this current depends on the amount of charges accumulated in the charge accumulation electrode 5, so that the amount of the current is detected. Then, by the magnitude of the detected amount of the current, written information (whether writing has been performed or not) is determined.

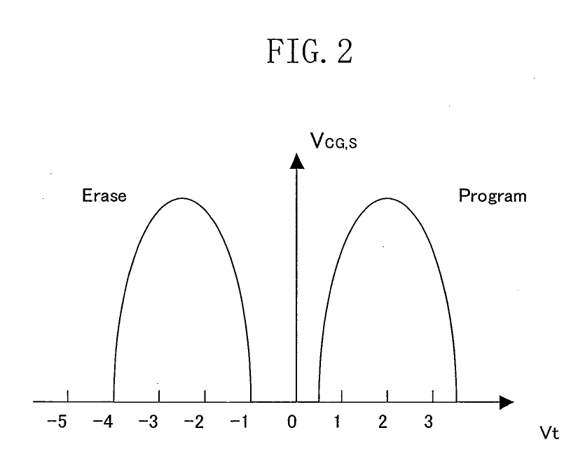

FIG. 2 roughly shows the distributions of the threshold voltages Vt of the memory cell of the nonvolatile semiconductor memory device according to the first embodiment, which are obtained after the writing and after the erasing. By the writing and erasing operations described above, the cell is made in the state of high Vt after the writing, while the cell is made in the state of low Vt after the erasing. The both states differ in sign. By the structure described above, the nonvolatile semiconductor memory device according to the first embodiment can provide a p-channel type flash memory which can attain miniaturization of memory cells and concurrently can maintain the advantage of the p-channel type flash memory that a margin for the set value of Vt can be widened and power consumption can be reduced.

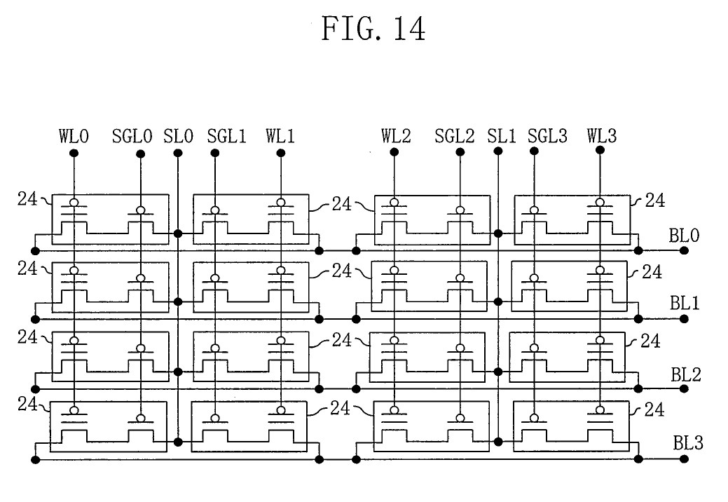

FIG. 14 is a circuit diagram of the first embodiment. In FIG. 14, the memory cells 24, 24, . . . are arranged in the column and row directions. The control electrodes extend continuously in the column direction to form word lines WL0, WL1, . . . . The select electrodes extend continuously in the column direction to form select gate lines SGL0, SGL1, . . . . In addition, the p-type source regions of the multiple memory cells 24, 24, . . . aligned in the column direction are connected to each other to form source lines SL0, SL1, extending in the column direction, and the p-type drain regions thereof aligned in the row direction are connected to each other to form bit lines BL0, BL1, . . . extending in the row direction. That is to say; a plurality of source lines SL0, SL1, . . . extending in the column direction and substantially parallel to each other are provided and each said source line is formed so that a set of the p-type source regions aligned in the column direction are connected to each other. Further, a plurality of bit lines BL0, BL1, . . . extending in the row direction and substantially parallel to each other are provided and each said bit line is formed so that a set of the p-type drain regions aligned in the row direction are connected to each other.

### Second Embodiment

In a second embodiment of the present invention, in contrast to the first embodiment, the state in which electrons are pulled out from the charge accumulation electrode 5 is defined as the state of being written, and the state in which electrons are injected into and accumulated in the charge accumulation electrode 5 is defined as the state of being erased.

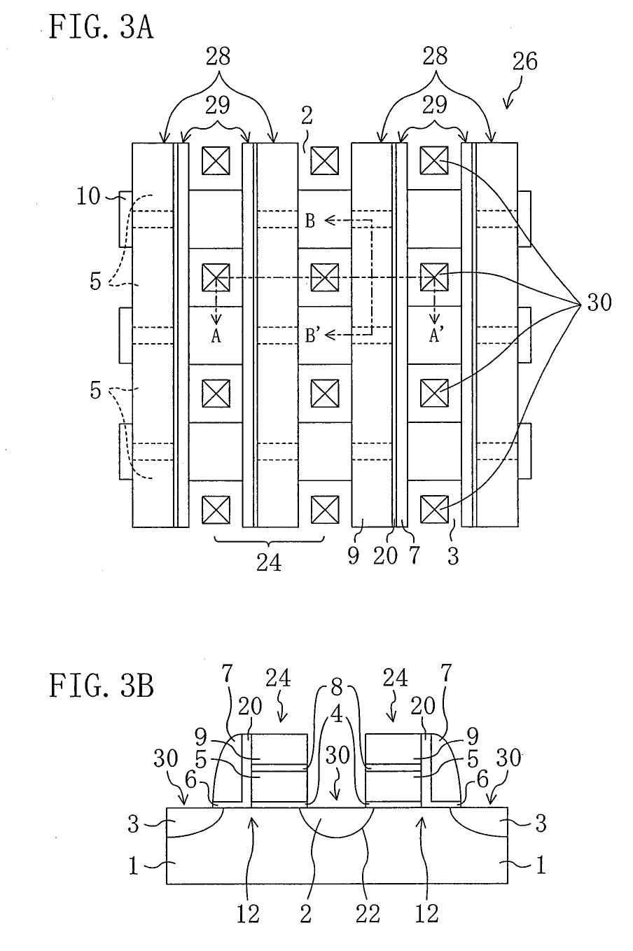

The structure of a nonvolatile semiconductor memory device according to the second embodiment of the present invention will be described with reference to FIG. 3. Note that source lines and bit lines are omitted in FIG. 3, but in fact they are on the memory cells 24, 24, . . . .

FIG. 3 shows the structure of a 2T type memory cell of the device according to the second embodiment. FIG. 3A is a plan layout view of a memory cell 24, and FIG. 3B is a sectional view taken along the line A-A′ in FIG. 3A. As shown in FIG. 3, the structure of the memory cell 24 has the same configuration as that of the first embodiment, but these structures differ in the arrangement of the source and the drain. Also in the second embodiment, like the first embodiment, the multiple memory cells 24, 24, . . . are arranged in the vertical and horizontal directions in FIG. 3A to constitute a memory cell array 26.

A p-type source region 2 and two p-type drain regions 3 and 3 are formed to extend inwardly from the surface of an n-type semiconductor layer 1. Two channel regions 12 and 12 (portions of the n-type semiconductor layer 1) are interposed between the p-type source region 2 and the two p-type drain regions 3 and 3, respectively. Across (in the position overlapping) parts of the upper portions of the two channel regions 12 and 12 and part of the upper portion of the p-type source region 2, two charge accumulation electrodes 5 and 5 are formed to interpose first insulating films 4 and 4 as tunnel insulating films therebetween, respectively. Above the charge accumulation electrodes 5 and 5, two control electrodes 9 and 9 are formed with second insulating films 8 and 8 interposed therebetween, respectively.

Across (in the position overlapping) parts of the upper portions of the channel regions 12 and 12 and parts of the upper portions of the p-type drain regions 3 and 3, two select electrodes 7 and 7 are formed with third insulating films 6 and 6 interposed therebetween, respectively. The select electrodes 7 and 7 are adjacent to side walls of the charge accumulation electrodes 5 and 5 and the control electrodes 9 and 9, which are located on the channel regions 12 and 12, respectively, so that fourth insulating films 20 and 20 are interposed between the respective side walls and select electrodes. The shapes of the two adjacent memory cells 24 and 24 shown in FIG. 3B are symmetrical with respect to the p-type source region 2. Specifically, in the two adjacent memory cells 24 and 24, side walls exposing the floating electrodes 5 and 5 and the control electrodes 9 and 9 face each other, and the select electrodes 7 and 7 are formed on the respective side walls opposite to the facing side walls. The adjacent memory cells 24 and 24 share the p-type source region 2 and are arranged symmetrically with respect to the p-type source region 2. That is to say, the second embodiment is characterized in that the p-type source region and the p-type drain region are arranged in opposite relation to those in the first embodiment. Even if this structure is applied to the device, the area occupied by the memory cell 24 can be reduced with the advantage of the 2T type memory cell maintained as in the case of the first embodiment.

A method for performing writing in the nonvolatile semiconductor memory device according to the second embodiment will be described below.

First, a negative potential necessary for writing (for example, −8.5 V) is applied to the control electrode 9, a potential preventing occurrence of disturbance (for example, a ground potential or the state of being open) is applied to the p-type source region 2, a ground potential is applied to the n-type semiconductor layer 1 and the select electrode 7, and a positive potential necessary for writing (for example, 8.5 V) is applied to the p-type drain region 3. Thereby, electrons are emitted from the charge accumulation electrode 5 through the first insulating film 4 to the p-type drain region 3, thereby performing writing. That is to say, in the second embodiment, the state in which electrons are pulled out from the charge accumulation electrode 5 is the state of being written. Such an electron emitting arises by utilizing FN tunneling phenomenon (Fowler-Nordheim tunneling). In addition, this writing is performed on a single bit of each memory cell 24 by selecting a bit line (not shown) connected to a contact 30 with the drain region 3 and a word line used also as the control electrode 9.

Next description will now be made of an erasing method of this nonvolatile semiconductor memory device.

A positive potential necessary for erasing (for example, 8 V) is applied to the control electrode 9, and a negative potential necessary for erasing (for example, −5 V) is applied to the source region 2. The select electrode 7 and the drain region 3 are set open, and the n-type semiconductor layer 1 is set at Vcc (for example, 3 V). Thereby, band-to-band tunneling is generated around a pn junction 22 of the source region 2 to produce electron-hole pairs. Of the pairs, the electrons are accelerated in the channel direction by a horizontal electric field to become electrons with high energies (hot electrons). At this time, since a positive potential is applied to the control electrode 9, these hot electrons can be easily injected into the first insulating film 4 to reach the charge accumulation electrode 5, thereby performing erasing. That is, in the second embodiment, the state in which electrons are injected into and accumulated in the charge accumulation electrode 5 is the state of being erased.

Of the electron-hole pairs produced by the band-to-band tunneling in this erasing, the holes are pulled to the source region 2 and scatter in the source region 2 having a high hole density. By the scattering, the energies of the holes are taken away, so that the holes are never changed to hot holes. Therefore, similarly to the technique described in Japanese Unexamined Patent Publication No. H9-8153, the holes having changed to hot holes will not be injected into the tunnel oxide film 4. Therefore, the problem of a reduced reliability associated with hole injection can be avoided.

Furthermore, a voltage higher in the negative direction than that in the erasing using the above-mentioned band-to-band tunneling can be applied to the source region 2 to generate avalanche breakdown at the pn junction 22 of the source region 2. Current occurring by the avalanche breakdown generates hot electrons, and the hot electrons are injected into the charge accumulation electrode 5 by a positive potential applied to the control electrode 9. Erasing can be performed also by such a procedure.

In the nonvolatile semiconductor memory device according to the second embodiment, by selecting a source line (not shown) connected to the contact 30 with the source region 2, the erasing is performed by one operation on all the memory cells belonging to the selected source line. In this erasing, the source line may be divided into several sectors and the erasing may be performed on each sector.

Next description will now be made of a reading method of this nonvolatile semiconductor memory device.

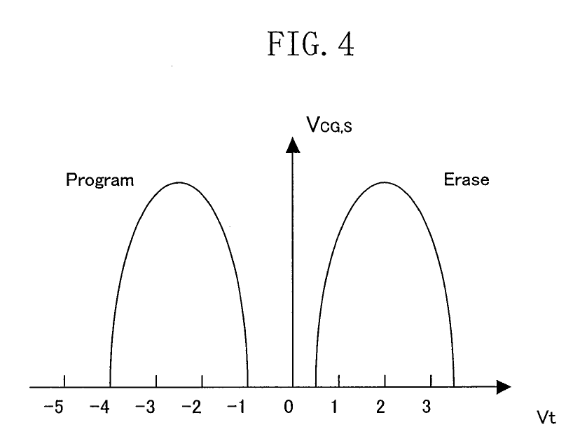

A positive potential (for example, 1.2 V) is applied to the p-type source region 2, Vcc (for example, 3 V) is applied to the p-type drain region 3, the control electrode 9 and the n-type semiconductor layer 1, and a ground potential is applied to the select electrode 7. By such a condition, current flows between the source and the drain. The amount of this current depends on the amount of charges accumulated in the charge accumulation electrode 5, so that the amount of the current is detected to perform reading. FIG. 4 roughly shows the threshold voltage distributions of the memory cell transistor of the nonvolatile semiconductor memory device according to the second embodiment, which are obtained after the writing and after the erasing. By the writing and erasing operations described above, the cell can be made in the state of low Vt after the writing (negative Vt), while the cell can be made in the state of high Vt (positive Vt) after the erasing. Thus, the both states are allowed to differ in sign, so that margins for the Vt values of the both states can be widened.

Also with the nonvolatile semiconductor memory device of the second embodiment, similarly to the first embodiment, miniaturization of the memory cell can be accomplished while the advantage of the p-channel type flash memory of 2T structure described in U.S. Pat. No. 5,912,842 is maintained. Furthermore, as is apparent from the voltage application method to the source 3, the drain 2, the n-type semiconductor layer 1, and the control electrode 9 in the writing and from the driving method of the device in the writing, the problem of the disturbance in the writing shown in the first embodiment will not arise. Therefore, a p-channel type flash memory can be provided which has a more widened operating margin than the first embodiment. Accordingly, the second embodiment is superior to the first embodiment in that no disturbance occurs.

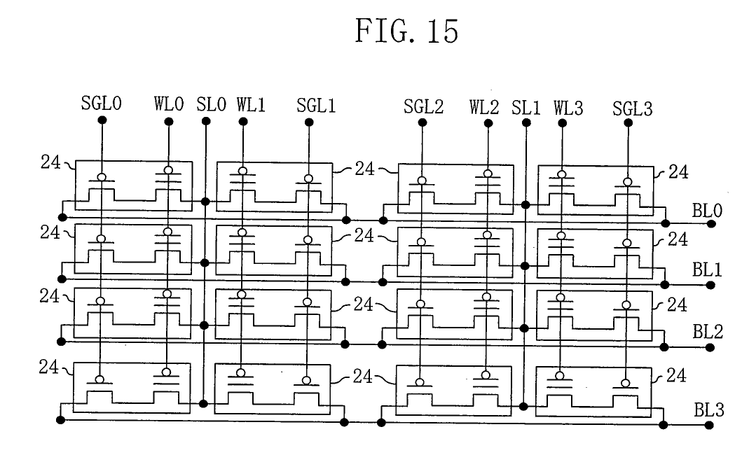

FIG. 15 is a circuit diagram of the second embodiment. In FIG. 15, the memory cells 24, 24, . . . are arranged in the column and row directions. The control electrodes extend continuously in the column direction to form word lines WL0, WL1, . . . . The select electrodes extend continuously in the column direction to form select gate lines SGL0, SGL1, . . . . In addition, the p-type source regions of the multiple memory cells 24, 24, . . . aligned in the column direction are connected to each other to form source lines SL0, SL1, . . . extending in the column direction, and the p-type drain regions thereof aligned in the row direction are connected to each other to form bit lines BL0, BL1, . . . extending in the row direction. That is to say, a plurality of source lines SL0, SL1, . . . extending in the column direction and substantially parallel to each other are provided and each said source line is formed so that a set of the p-type source regions aligned in the column direction are connected to each other. Further, a plurality of bit lines BL0, BL1, . . . extending in the row direction and substantially parallel to each other are provided and each said bit line is formed so that a set of the p-type drain regions aligned in the row direction are connected to each other.

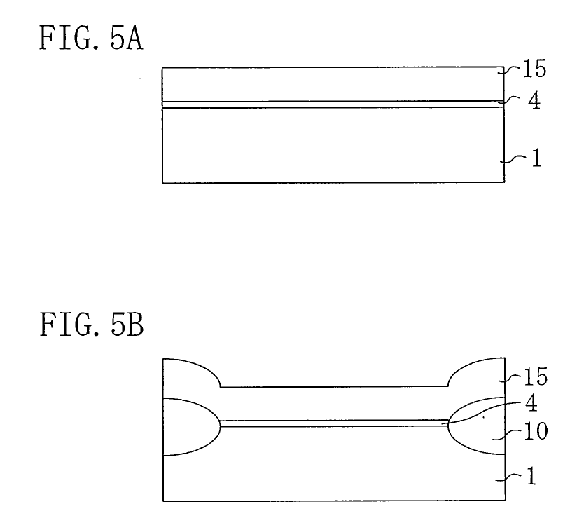

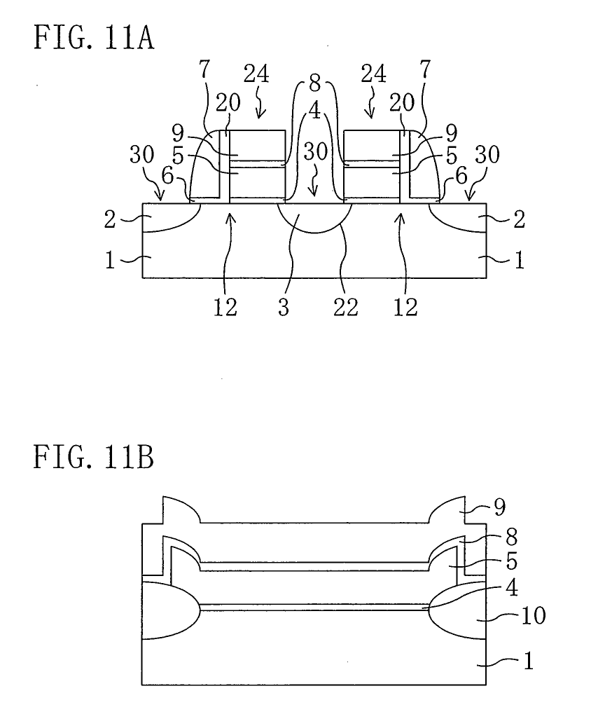

Next, a fabrication method of the nonvolatile semiconductor memory device according to the first and second embodiments of the present invention will be concretely described with reference to FIGS. 5 to 11. This fabrication method is common to the memory devices of the first and second embodiments, but the both embodiments are slightly different only in FIG. 11. This difference will be described later. FIGS. 5 to 11 are sectional views showing fabrication steps of these nonvolatile semiconductor memory devices. Of FIGS. 5 to 11, FIGS. 5A to 11A show cross sections taken along the line A-A′ in FIG. 1 or 3, and FIGS. 5B to 11B show cross sections taken along the line B-B′ in FIG. 1 or 3.

Referring to FIG. 5, first, an active region isolated by isolation regions 10 such as LOCOS is formed on the n-type semiconductor layer 1. On the active region, a first insulating film 4 is formed which serves as the tunnel oxide film.

Then, on the surfaces of the first insulating film 4 and the isolation region 10, a first conductor film 15 which is made of, for example, a silicon film and which will later be the charge accumulation electrode is deposited by CVD or the like.

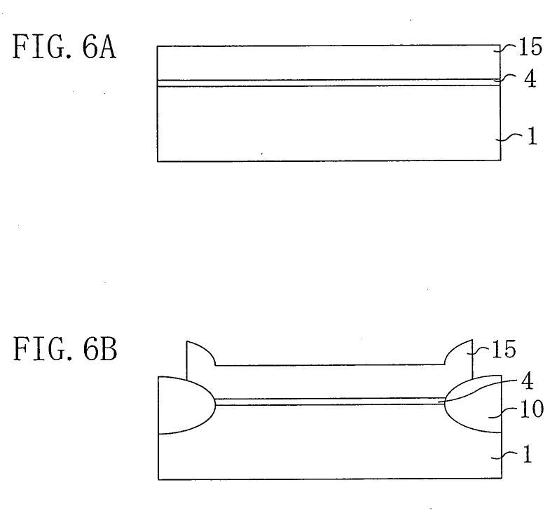

Next, as shown in FIG. 6, the first conductor film 15 is selectively etched and removed. The direction in which the film portion is removed by this etching is the row direction (horizontal direction) in FIG. 1A or 3A, that is, the direction intersecting the longitudinal direction in which the word line as the control electrode extends. In this figure, the edges (wall faces) of the unremoved portion perpendicular to the word line are formed.

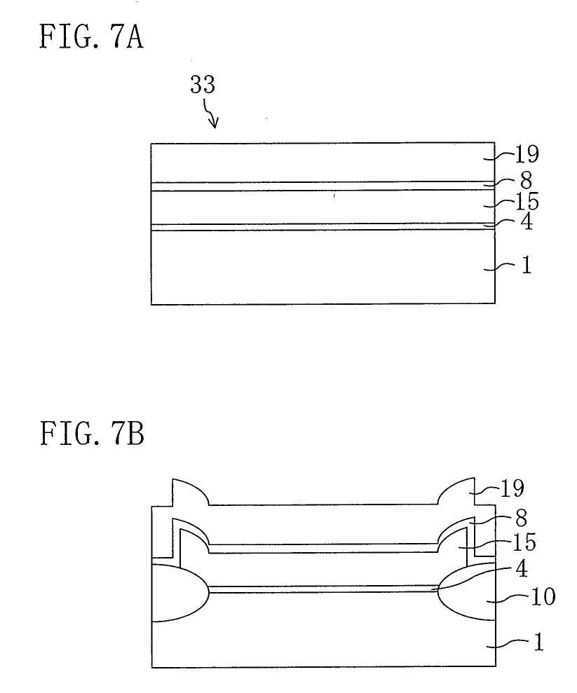

As shown in FIG. 7, a second insulating film 8 such as a silicon oxide film is then formed on the first conductor film 15.

On the second insulating film 8, a second conductor film 19 such as a silicon film containing impurities is deposited. The second conductor film 19 will later serve as the control electrode. Note that the first conductor film 15, the second insulating film 8, and the second conductor film 19 constitute an electrode structure layer 33.

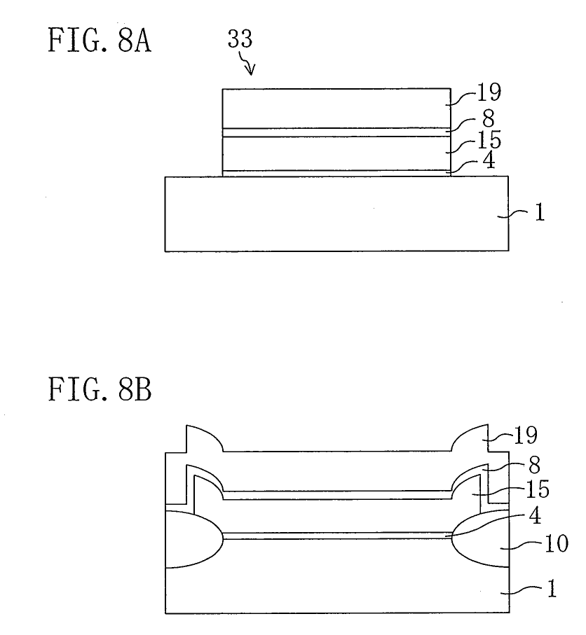

Next, as shown in FIG. 8, part of the electrode structure layer 33 is selectively etched and removed. This etching is performed so that part of the electrode structure layer 33 is removed in the perpendicular direction to the surface of the n-type semiconductor layer 1 to produce a wall face perpendicular to the surface of the n-type semiconductor layer 1. A pattern formed by this etching is a pattern of multiple parallel strips each extending in the substantially orthogonal direction to the direction in which the removal of the first conductor film 15 has previously been conducted by etching, that is, in the column direction (vertical direction). In the formed pattern, a portion that will finally be formed into two control electrodes in adjoining arrangement is of undivided form.

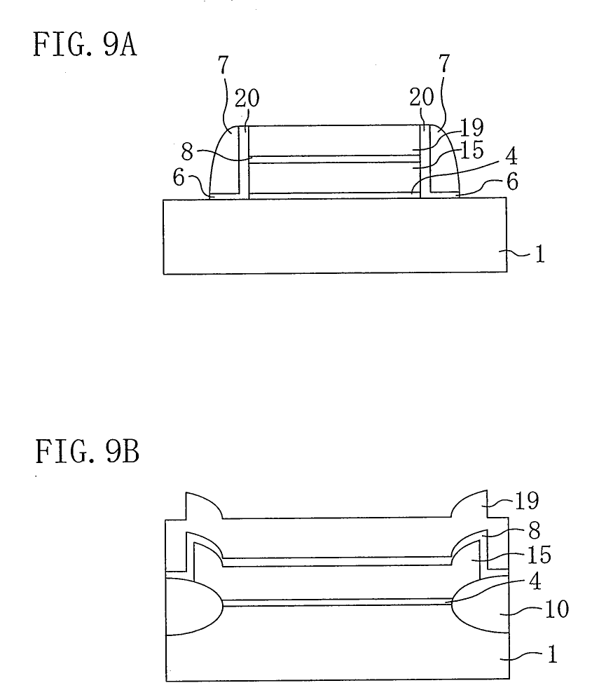

As shown in FIG. 9, on the surfaces of the n-type semiconductor layer 1 and the second conductor film 19, a third insulating film 6 is grown by thermal oxidation or the like. On the insulating film 6, a third conductor film is stacked which will serve as the select electrode 7 and which is made of a silicon film containing impurities, and the third conductor film is etched by a well-known anisotropic etching to form the select electrodes 7 and 7. In this step, the insulating films formed on the side walls of the first conductor film 15, the second insulating film 8, and the second conductor film 19, which are exposed by the etching serve as a fourth insulating film 20, and each of the select electrodes 7 is formed to adjoin the first conductor film 15, the second insulating film 8 and the second conductor film 19 with the fourth insulating film 20 interposed between the select electrode 7 and each of these films. Thereby, the third insulating film 6 formed on the n-type semiconductor layer 1 just serves as the gate insulating film of the select transistor having the select electrode 7.

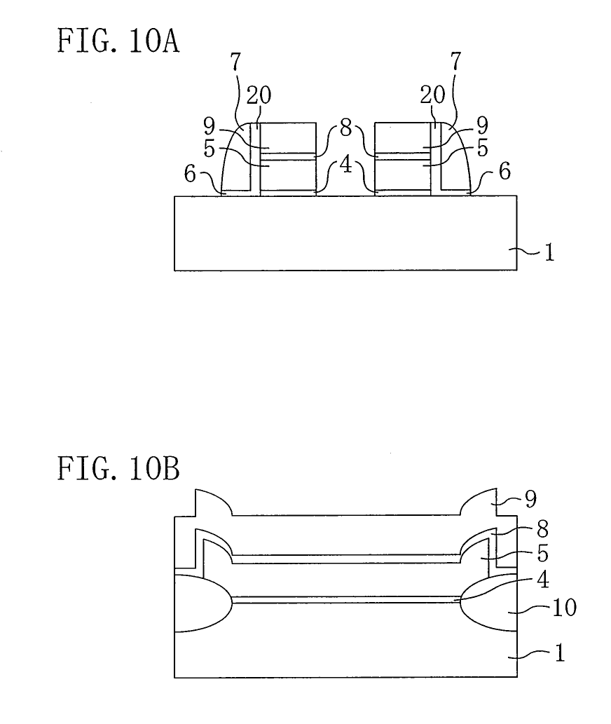

Then, as shown in FIG. 10, the center portion of the strip electrode structure layer 33 is etched and removed along the direction in which the strip extends, thereby dividing the single strip in two. Thus, the charge accumulation electrodes 5 and 5 and the control electrodes 9 and 9 as the two word lines are formed at a time in isolated arrangement. This step can easily form a pair of memory cells composed of two transistors in symmetrical configuration.

Then, as shown in FIG. 11, by a well-known ion implantation, p-doped layers serving as the p-type source regions 2 and the p-type drain region 3 are formed to extend inwardly from the surface of the n-type semiconductor layer 1. FIG. 11 shows the nonvolatile semiconductor memory device according to the first embodiment, and in the second embodiment, the drain region and the source region in FIG. 11 are replaced with each other. Thereafter, the formed source region 2 and drain region 3 are connected through the contacts 30 formed thereon to a source line and a bit line made of aluminum alloy, respectively. Thus, the nonvolatile semiconductor memory device according to the first and second embodiments can be provided. Note that subsequent metallization process, passivation film formation process, and bonding pad formation process are omitted. In the fabrication method described above, the transistors are formed in the n-type semiconductor layer (n-well) 1 to constitute a memory, but it is also acceptable to form transistors in a p-type semiconductor layer to constitute a memory. In such a case, the source and drain regions are of n-type.

In the semiconductor memory device and the fabrication method thereof according to the present invention, the select electrodes are provided to adjoin the side walls of the memory cell transistors composed of the charge accumulation electrode and the control electrode. Therefore, the problem of a large area occupied by the 2T-type memory cell, which conventionally exists, can be solved. Moreover, the semiconductor memory device having the structure of the present invention can implement the driving method like the procedure of the present invention.

In the driving method of the device according to the present invention, electrons are injected and emitted through the first insulating film as the tunnel insulating film. This prevents conventional transfer of holes having changed to hot holes through the first insulating film, so that driving of the p-channel type flash memory having an improved reliability of the flash memory can be attained. Moreover, since the device of the present invention is of p-channel type with 2T structure, the advantage this type has can be exerted of low power consumption and reliable reading resulting from a wide operating margin (margins for the set value of Vt serving as different pieces of stored information and preventing the occurrence of overerasing). This greatly contributes to enhanced performance of a semiconductor memory device, in particular a flash memory.

1-18. (canceled)

19. A method for fabricating a nonvolatile semiconductor memory device, comprising the steps of:
forming a first insulating film on a semiconductor layer of a first conductivity type;
depositing a first conductor film on the first insulating film;
selectively removing part of the first conductor film;
forming a second insulating film on the first conductor film;
depositing a second conductor film on the second insulating film;
removing parts of an electrode structure layer composed of the first conductor film, the second insulating film, and the second conductor film selectively and perpendicularly to the surface of the semiconductor layer of the first conductivity type, thereby forming the unremoved parts in multiple strips extending in the substantially orthogonal direction to the direction in which the removal of the first conductor film has been conducted;
forming a third insulating film on portions of the surface of the semiconductor layer of the first conductivity type from which the electrode structure layer has been removed, forming fourth insulating films on both side walls of each said strip of the electrode structure layer, and then forming third conductor films on the fourth insulating films, respectively, to provide the third conductor films as select electrodes;
removing a center portion of each said strip of the electrode structure layer along the direction in which the strip extends, thereby dividing the single strip in two; and
forming a doped region of a second conductivity type in the semiconductor layer of the first conductivity type by using the electrode structure layer as a mask, the second conductivity type being different from the first conductivity type.

20. The method of claim 19,
wherein the first conductivity type is an n-type, and the second conductivity type is a p-type.
